(19) United States
(12) Patent Application Publication
(10) Pub. No.: US 2016/0112039 A1
(43) Pub. Date: Apr. 21, 2016

(54) MULTI-VOLTAGE DRIVING CIRCUIT

(71) Applicant: INTEGRATED SOLUTIONS TECHNOLOGY INC., Taipei City (TW)

(72) Inventor: QING-LONG JIAN, SHENZHEN CITY (CN)

(21) Appl. No.: 14/693,284

(22) Filed: Apr. 22, 2015

(30) Foreign Application Priority Data
Oct. 15, 2014 (CN) 201410545215.1

(51) Int. Cl. H03K 17/00

(52) U.S. Cl. CPC H03K 17/007

(57) ABSTRACT

A multi-voltage driving circuit is provided. The multi-voltage driving circuit has a master capacitor and a plurality of slave capacitors, which are connected in series. The multi-voltage driving circuit averages the voltage of the master capacitor and the voltages of the slave capacitors by turning on or turning off a first master switch, a second master switch, and a plurality of slave switch sets continuously, thereby the voltages of the master capacitor and the slave capacitors become equal gradually and the multi-voltage driving circuit generates a plurality of divided voltages. Because the master capacitor and slave capacitors have no power consumption and the first master switch, the second master switch, and the slave switch sets have less power consumption, the multi-voltage driving circuit may be adapted for low-power operation and generate accurate divided voltages.

### BACKGROUND

1. Technical Field

The present invention relates to a multi-voltage driving circuit, in particular, to a multi-voltage driving circuit without resistors.

2. Description of Related Art

In integrated circuits, voltage division circuits are used for generating different divided voltages to back-end devices, to provide back-end devices for doing other analyses and applications.

The traditional voltage division circuit is configured for resistors connected in series in the same current path to accordingly generate divided voltages, as shown in FIG. 1. The multi-voltage driving circuit 10 is configured for four resistors R1, R2, R3, and R4, which are connected in series in a current path I1. The resistors R1˜R4 have the same resistance value. One end of the multi-voltage driving circuit 10 receives the voltage VC and the other end of the multi-voltage driving circuit 10 connects to ground. Therefore, the multi-voltage driving circuit 10 respectively generates the divided voltages A1, A2, and A3 among the resistors R1˜R4 according to the resistance value of the resistors R1˜R4. Meanwhile, the divided voltages A1˜A3 are defined by 1/4VC, 2/4VC, and 3/4VC respectively. The power consumption of each resistor R1˜R4 of the multi-voltage driving circuit 10 is I1²*R1, I1²*R2, I1²*R3, and I1²*R4 respectively.

Therefore, for the requirement of the low-power operation, a multi-voltage driving circuit that still uses resistors to generate the divided voltages may not drive because of the resistors generating too much power consumption.

To address the above issues, the inventor strives via associated experience and research to present the instant disclosure, which can effectively improve the limitation described above.

### SUMMARY

Accordingly, an objective of the instant disclosure is to provide a multi-voltage driving circuit, which substitutes the structure of capacitors and switches for the structure of the resistors. Therefore, the multi-voltage driving circuit can output different divided voltages by the method of averaging the voltages of the capacitors. The multi-voltage driving circuit does not have other power consumption except for the switches which have less power consumption. Compared to a traditional multi-voltage driving circuit, the multi-voltage driving circuit of the instant disclosure may be more adapted for low-power operation.

An exemplary embodiment of the instant disclosure provides a multi-voltage driving circuit. The multi-voltage driving circuit includes a high-end, a low-end, a plurality of slave capacitors, a voltage element, a switch element, and a controller. The high-end has a high voltage. The low-end has a low voltage. The slave capacitors are connected in series between the high-end and the low-end. The voltage element is connected in series to the high-end, the slave capacitors, and the low-end. The voltage element has a master capacitor, a first master switch, and a second master switch, wherein the first master switch is connected in series to one end of the master capacitor and the second master switch is connected in series to the other end of the master capacitor. The switch element is electrically connected among the voltage element and the slave capacitors. The switch element has a plurality of slave switch sets, wherein one end of each slave switch set is electrically connected to the voltage element, and the other end of each slave switch is respectively and electrically connected to the slave capacitors. The controller is electrically connected to the voltage element and the switch element. The controller is configured for generating a driving signal with a driving period to periodically control the first master switch, the second master switch, and the slave switch sets according to the driving signal. The controller simultaneously turns on the first master switch and the second master switch at least once during the driving period, and when the controller simultaneously turns on the first master switch and the second master switch, turns off the slave switch sets. The controller respectively turns on the slave switch sets at least once during the driving period, and when the controller turns on the corresponding slave switch set, turns off the first master switch, the second master switch, and the slave switch sets without the turned-on slave switch sets.

An exemplary embodiment of the instant disclosure provides a multi-voltage driving circuit. The multi-voltage driving circuit includes a high-end, a low-end, a plurality of slave capacitors, a plurality of voltage elements, a plurality of switch elements, and a controller. The high-end has a high voltage. The low-end has a low voltage. The slave capacitors are connected in series between the high-end and the low-end. The voltage elements are connected in series to the high-end, the slave capacitors, and the low-end. The voltage elements are connected in parallel with each other, wherein each voltage element has a master capacitor, a first master switch, and a second master switch. The first master switch is connected in series to one end of the master capacitor, and the second master switch is connected in series to the other end of the master capacitor. One end of each switch element is respectively and electrically connected to the voltage elements, and the other end of each switch element is respectively and electrically connected to a part of the slave capacitors. Each switch element has a plurality of slave switch sets. The number of the slave switch sets of each switch element is equal to the number of the corresponding slave capacitors. One end of each slave switch set is electrically connected to the corresponding voltage element. The other end of each slave switch set is electrically connected to the corresponding slave capacitor. The slave capacitors are respectively and electrically connected to at least one switch element. The controller is electrically connected to the voltage elements and the switch elements. The controller is configured for generating a plurality of driving signals. Each driving signal has a driving period. The controller periodically controls the first master switch and the second master switch of the voltage elements and the slave switch sets of the switch elements according to the driving signals. The controller simultaneously turns on the first master switch and the second master switch of the voltage elements at least once during the driving periods, and when the controller simultaneously turns on the first master switch and the second master switch of the voltage elements, turns off the slave switch sets of the switch elements. The controller respectively turns on the slave switch sets of the switch elements at least once during the driving periods, and when the controller respectively turns on the slave switch sets of the switch elements, turns off the first master switch and the second master switch of the voltage elements and the slave switch sets without the turned-on slave switch sets of the switch elements.

An exemplary embodiment of the instant disclosure provides a multi-voltage driving circuit. The multi-voltage driving circuit includes a high-end, a low-end, a plurality of slave capacitors, a voltage element, a switch element, and a controller. The high-end has a high voltage. The low-end has a low voltage. The voltage element is connected in series between the high-end and the first slave capacitor. The voltage element has a master capacitor, a first master switch, and a second master switch, wherein the first master switch is connected in series to one end of the master capacitor and the second master switch is connected in series to the other end of the master capacitor. The switch element is electrically connected among the voltage element, the slave capacitors, and the low-end. The switch element has a plurality of slave switch sets and an end switch set. One end of each slave switch set is electrically connected to the voltage element. The other end of each slave switch set is sequentially and electrically connected to two slave capacitors. One end of the end switch set is electrically connected to the voltage element. The other end of the end switch set is electrically connected to the last slave capacitor and the low-end. One end of each slave capacitor is electrically connected to the corresponding slave switch set and the other end of each slave capacitor is connected to ground. The controller is electrically connected to the voltage element and the switch element. The controller is configured for generating a driving signal with a driving period to control the first master switch, the second master switch, the slave switch sets, and the end switch set. The controller simultaneously turns on the first master switch and the second master switch at least once during the driving period, and when the controller simultaneously turns on the first master switch and the second master switch, turns off the slave switch sets and the end switch set. The controller respectively turns on the slave switch sets and the end switch set at least once during the driving period, when the controller turns on the corresponding slave switch set, turns off the first master switch, the second master switch, the end switch set, and the slave switch sets without the turned-on switch set, and when the controller turns on the corresponding end switch set, turns off the first master switch, the second master switch, and the slave switch sets.

In order to further understand the techniques, means and effects of the present invention, the following detailed descriptions and appended drawings are hereby referred to, such that, and through which, the purposes, features and aspects of the present disclosure can be thoroughly and concretely appreciated; however, the appended drawings are merely provided for reference and illustration, without any intention to be used for limiting the present invention.

### BRIEF DESCRIPTION OF THE DRAWINGS

The accompanying drawings are included to provide a further understanding of the present invention, and are incorporated in and constitute a part of this specification. The drawings illustrate exemplary embodiments of the present invention and, together with the description, serve to explain the principles of the present invention.

FIG. 1 is a diagram of a traditional multi-voltage driving circuit.

FIG. 2 is a diagram of a multi-voltage driving circuit according to an exemplary embodiment of the instant disclosure.

FIG. 3 is a diagram of a multi-voltage driving circuit according to the other exemplary embodiment of the instant disclosure.

FIG. 4 is a diagram of a multi-voltage driving circuit according to the other exemplary embodiment of the instant disclosure.

FIG. 5 is a diagram of a multi-voltage driving circuit according to the other exemplary embodiment of the instant disclosure.

FIG. 6 is a diagram of a multi-voltage driving circuit according to the other exemplary embodiment of the instant disclosure.

### DESCRIPTION OF THE EXEMPLARY EMBODIMENTS

Reference will now be made in detail to the exemplary embodiments of the present disclosure, examples of which are illustrated in the accompanying drawings. However, they may be embodied in different forms and should not be construed as being limited to the embodiments set forth herein. Wherever possible, the same reference numbers are used in the drawings and the description to refer to the same or like parts.

The instant disclosure provides a multi-voltage driving circuit. The multi-voltage driving circuit averages the voltage of a master capacitor and the voltages of slave capacitors by turning on or turning off a first master switch, a second master switch, and a plurality of slave switch sets continuously, thereby the voltages of the master capacitor and the slave capacitors become equal gradually and the multi-voltage driving circuit generates a plurality of divided voltages. Because the master capacitor and slave capacitors have no power consumption and the first master switch, the second master switch, and the slave switch sets have less power consumption, the multi-voltage driving circuit may be adapted for low-power operation.

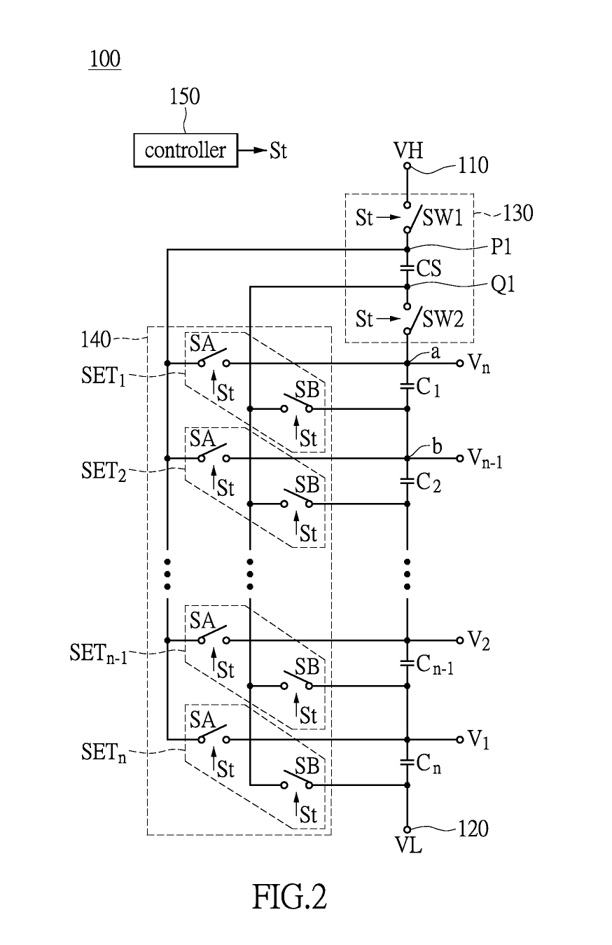

Firstly, please refer to FIG. 2, which a diagram of a multi-voltage driving circuit according to an exemplary embodiment of the instant disclosure. As shown in FIG. 2, the multi-voltage driving circuit 100 includes a high-end 110, a low-end 120, slave capacitors C1-Cn, a voltage element 130, a switch element 140, and a controller 150. The high-end 110 has a high voltage VH and the low-end 120 has a low voltage VL. The slave capacitors C1-Cn are connected in series between the high-end 110 and the low-end 120. The voltage element 130 is connected in series to the high-end 110, the slave capacitors C1-Cn, and the low-end 120. Accordingly, the voltage difference between the high-end 110 and the low-end 120 is the high voltage VH minus the low voltage VL, to generate a voltage range from the low voltage VL to the high voltage VH between the slave capacitors C1-Cn and the voltage element 130. In the actual structure, the low-end 120 may connect to ground to cause the low voltage VL to be 0V, and the instant disclosure is not limited thereto.

The voltage element 130 has a master capacitor CS, a first master switch SW1, and a second master switch SW2. The first master switch SW1 is connected in series to one end P1 of the master capacitor CS. The second master switch SW2 is connected in series to the other end Q1 of the master capacitor CS. The voltage element 130 can be configured between the high-end 110 and the first slave capacitor C1, two adjacent slave capacitors C1-Cn (e.g., the adjacent slave capacitors C3 and C4), the low-end 120 and the last slave capacitor Cn (i.e., the end P1 of the master capacitor CS is connected in series to the last slave capacitor Cn through the first master switch SW1, and the other end Q1 of the master capacitor CS is connected in series to the low-end 120 through the second master switch SW2), etc. The instant disclosure is not limited thereto.

In the instant disclosure, the voltage element 130 is configured between the high-end 110 and the first slave capacitor C1. More specifically, the end P1 of the master capacitor CS is connected in series to the high-end VH through the first master switch SW1. The other end Q1 of the master capacitor CS is connected in series to the first slave capacitor C1 through the second master switch SW2.

The switch element 140 is electrically connected among the voltage element 130 and the slave capacitors C1-Cn. The switch element 140 has a plurality of slave switch sets SET1-SETn to adjust the voltage of the master capacitor CS and the voltages of the slave capacitors C1-Cn according to turning on or turning off the slave switch sets SET1-SETn. One end of each slave switch set SET1-SETn is electrically connected to the voltage element 130. The other end of each slave switch set SET1-SETn is respectively and electrically connected to the slave capacitors C1-Cn.

In the instant disclosure, each slave switch set SET1-SETn has a first slave switch SA and a second slave switch SB. One end of the first slave switch SA is electrically connected to the end P1 of the master capacitor CS. The other end of the first slave switch SA is electrically connected to one end of the corresponding slave capacitor. One end of the second slave switch SB is electrically connected to the other end Q1 of the master capacitor CS. The other end of the second slave switch SB is electrically connected to the other end of the corresponding slave capacitor. Taking the slave switch set SET1 and the slave capacitor C1 as an example, one end of the first slave switch SA is electrically connected to the end P1 of the master capacitor CS. The other end of the first slave switch SA is electrically connected to the end a of the slave capacitor C1. One end of the second slave switch SB is electrically connected to the other end Q1 of the master capacitor CS. The other end of the second slave switch SB is electrically connected to the other end b of the slave capacitor C1.

The controller 150 is electrically connected to the voltage element 130 and the switch element 140. The controller 150 generates a driving signal St with a driving period (not shown in FIGs) to periodically control the first master switch SW1, the second master switch SW2, and the slave switch sets SET1-SETn according to the driving signal St, i.e., periodically turning on or turning off the first master switch SW1, the second master switch SW2, and the slave switch sets SET1-SETn. The controller 150 can be clock generator, waveform generator, or other electronic devices, which can periodically generate the driving signal St. The instant disclosure is not limited thereto.

During the driving period, the controller 150 simultaneously turns on the first master switch SW1 and the second master switch SW2 at least once and respectively turns on the slave switch sets SET1-SETn at least once. This means that the aforementioned switches are turned on at least once during the whole driving period. When the controller 150 turns on the first master switch SW1 and the second master switch SW2 according to the driving signal St, the controller 150 turns off the slave switch sets SET1-SETn. Then the multi-voltage driving circuit 100 increases the voltage of the master capacitor CS and the voltages of the slave capacitors C1-Cn according to the high voltage VH.

When the controller 150 turns on the corresponding slave switch set according to the driving signal St, the controller 150 turns off the first master switch SW1, the second master SW2, and the slave switch set without the turned-on switch set. Then the multi-voltage driving circuit 100 averages the voltage of the master capacitor CS and the voltage of the slave capacitor corresponding to the turned-on slave switch set. For example, when the controller 150 turns on the slave switch set SET1 according to the driving signal St, the controller 150 turns off the first master switch SW1, the second master switch SW2, and the slave switch set without the turned-on switch set SET2-SETn. Then the multi-voltage driving circuit 100 averages the voltage of the master capacitor CS and the voltage of the slave capacitor C1.

It is worth to note that the driving period can be designed by the connecting sequence of the first master switch SW1, the second master switch SW2, and the slave switch sets SET1-SETn. Therefore, the controller 150 firstly turns on the first master switch SW1 and the second master switch SW2, and then sequentially turns on the slave switch sets SET1-SETn. The driving period can be designed by other connecting sequences of the first master switch SW1, the second master switch SW2, and the slave switch sets SET1-SETn. For example, the controller 150 firstly turns on the first master switch SW1 and the second master switch SW2, then sequentially turns on the odd slave switch sets SET1, SET3, . . . , SETn−1, and finally sequentially turns on the even slave switch sets SET2, SET4, . . . , SETn. The instant disclosure does not limit the sequence of turning on the aforementioned switches.

In the situation of the controller 150 continuously generating the driving signal St with the driving period, the multi-voltage driving circuit 100 continuously averages the voltage of the master capacitor CS and the voltages of the slave capacitors C1-Cn, so that the voltages of the slave capacitors C1-Cn become equal gradually. The multi-voltage driving circuit 100 further generates a plurality of divided voltages V1-Vn. Each divided voltage V1-Vn is Vm=VL+m*(VH−VL)/(n+1), wherein 1<=m<=n.

As the aforementioned exemplary embodiments, because the capacitance values of the master capacitor CS and the slave capacitors C1-Cn do not influence the multi-voltage driving circuit 100 averaging the voltage of the master capacitor CS and the voltages of the slave capacitors C1-Cn, the capacitance values of the master capacitor CS and the slave capacitors C1-Cn need not be all equal. Therefore, the master capacitor CS and the slave capacitors C1-Cn are easily implemented in a manufacturing process. Moreover, when the capacitance values of the slave capacitor C1-Cn become larger, each of the divided voltages V1-Vn has less ripple voltage, so that the multi-voltage driving circuit 100 can stably output the divided voltages V1-Vn. In addition, when the controller 150 generates the driving signal St with the shorter driving period, the first master switch SW1, the second master switch SW2, and the slave switch sets SET1-SETn have faster switching frequency and lower parasitic resistance, so that the aforementioned switches have less power consumption. Accordingly, the multi-voltage driving circuit is adapted for low-power operation.

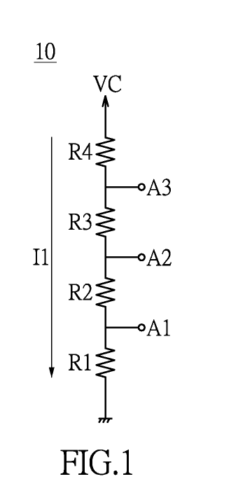

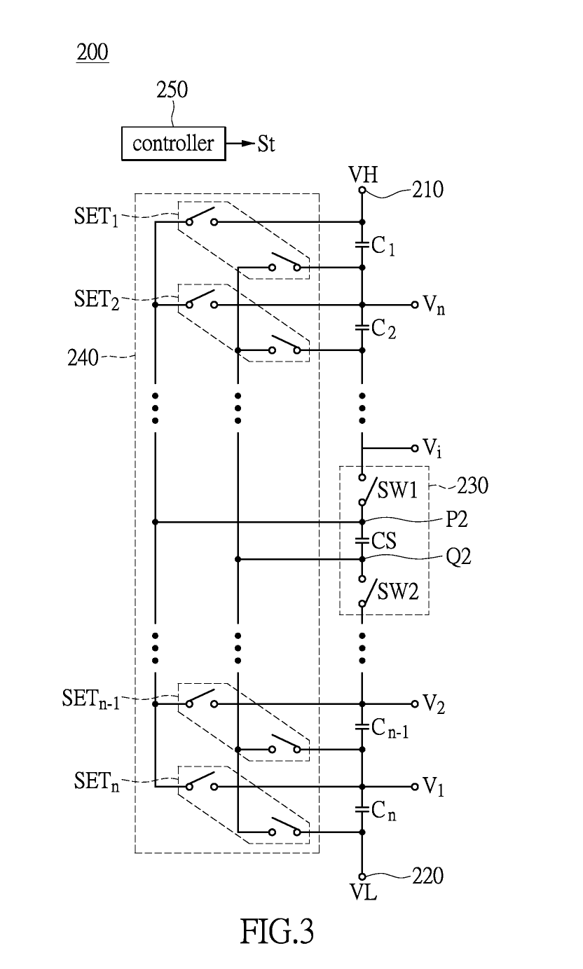

Next, please refer to FIG. 3, which shows a diagram of a multi-voltage driving circuit according to another exemplary embodiment of the instant disclosure. As shown in FIG. 3, the multi-voltage driving circuit 200 includes a high-end 210, a low-end 220, a plurality of slave capacitors C1-Cn, a voltage element 230, a switch element, and a controller 250. Compared to the multi-voltage driving circuit 100 in FIG. 1, the difference of the multi-voltage driving circuit 200 in FIG. 3 is that the voltage element 230 is configured between two adjacent slave capacitors. More specifically, one end P2 of the master capacitor CS is connected in series to one of two adjacent slave capacitors through the first master switch SW1. The other end Q2 of the master capacitor CS is connected in series to the other of two adjacent slave capacitors through the second master switch SW2. Taking the voltage element 230 connected in series between the fifth slave capacitor C5 and the sixth slave capacitor C6 (i.e., between two adjacent slave capacitors) as an example, the end P2 of the master capacitor CS is connected in series to the fifth slave capacitor C5 through the first master switch SW1. The other end Q2 of the master capacitor CS is connected in series to the sixth slave capacitor C6 through the second master switch SW2. The connection relationships and operations among the high-end 210, the low-end 220, the slave capacitors C1-Cn, the slave switch sets SET1-SETn, the voltage element 230, the switch element 240, and the controller 250 are the same as that of the high-end 110, the low-end 120, the slave capacitors C1-Cn, the slave switch sets SET1-SETn, the voltage element 130, the switch element 140, and the controller 150 as shown in FIG. 2, so their detailed description is omitted.

Therefore, in the situation of the controller 250 continuously generating the driving signal St with the driving period, the multi-voltage driving circuit 200 continuously averages the voltage of the master capacitor CS and the voltages of the slave capacitors C1-Cn, so that the voltages of the slave capacitors C1-Cn become equal gradually. The multi-voltage driving circuit 200 further generates a plurality of divided voltages V1-Vn. Each divided voltage V1-Vn is Vm=VL+m*(VH−VL)/(n+1), wherein 1<=m<=n.

As the aforementioned exemplary embodiments, the multi-voltage driving circuit 100 and 200 are designed by the structure of the master capacitor CS, the slave capacitors C1-Cn, the first master switch SW1, second master switch SW2, and the slave switch sets SET1-SETn. Because the master capacitor CS and the slave capacitors C1-Cn have no power consumption, the multi-voltage driving circuits 100 and 200 generate more accurate divided voltages V1-Vn. In addition, because the first master switch SW1, the second master switch SW2, and the slave switch sets SET1-SETn have less power consumption, the multi-voltage driving circuits 100 and 200 are adapted for low-power operation.

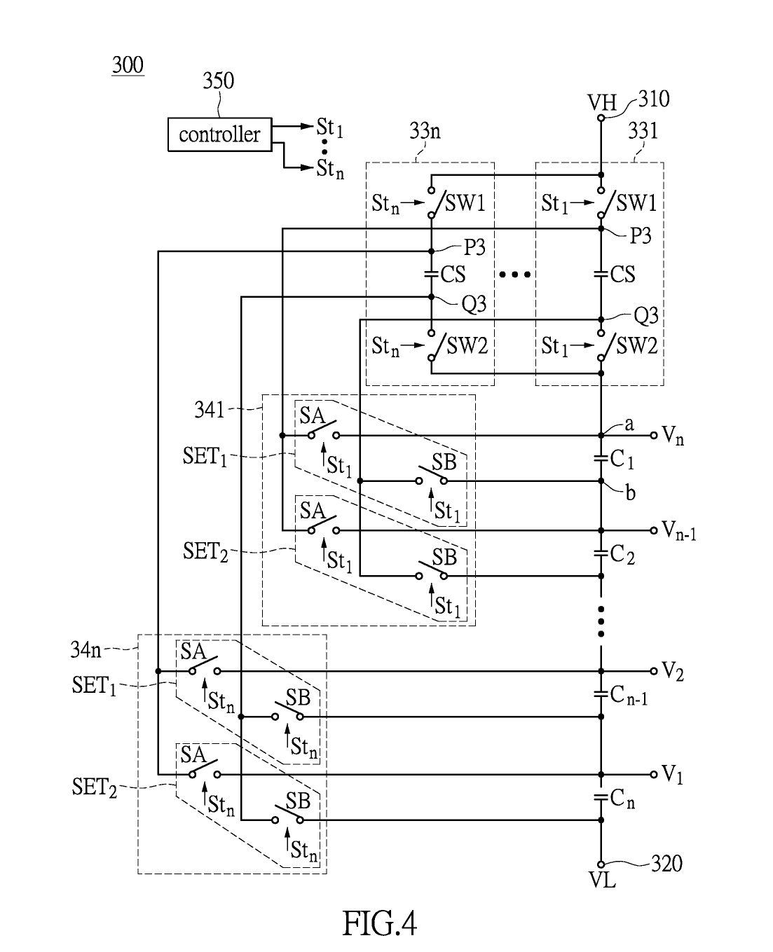

Next, please refer to FIG. 4, which shows a diagram of a multi-voltage driving circuit according to the other exemplary embodiment of the instant disclosure. As shown in FIG. 4, the multi-voltage driving circuit 300 includes a high-end 310, a low-end 320, a plurality of slave capacitors C1-Cn, a plurality of voltage elements 331-33n, a plurality of switch elements 341-34n, and a controller 350. The high-end 310 has a high voltage VH and the low-end 320 has a low voltage VL. The slave capacitors C1-Cn are connected in series between the high-end 310 and the low-end 320. The voltage elements 331-33n are connected in series to the high-end 310, the slave capacitors C1 -Cn, and the low-end 320 and the voltage elements 331-33n are connected in parallel with each other. Accordingly, the voltage difference between the high-end 310 and the low-end 320 is the high voltage VH minus the low voltage VL, to generate a voltage range from the low voltage VL to the high voltage VH between the slave capacitors C1-Cn and the voltage elements 331-33n. In the actual structure, the low-end 320 may connect to ground to cause the low voltage VL to be 0V, and the instant disclosure is not limited thereto.

Each voltage element 331-33n has a master capacitor CS, a first master switch SW1, and second master switch SW2. In each voltage element 331-33n, the first master switch SW1 is connected in series to one end P3 of the master capacitor CS and the second master switch SW2 is connected in series to the other end Q3 of the master capacitor CS. The voltage elements 331-33n can be configured between the high-end 310 and the first slave capacitor C1, two adjacent slave capacitors C1-Cn (e.g., the adjacent slave capacitors C3 and C4), the low-end 320 and the last slave capacitor Cn (i.e., the end P3 of each master capacitor CS is connected in series to the last slave capacitor Cn through the corresponding first master switch SW1, and the other end Q1 of each master capacitor CS is connected in series to the low-end 320 through the corresponding second master switch SW2), etc. The instant disclosure is not limited thereto.

In the instant disclosure, the voltage elements 331-33n are configured between the high-end 310 and the first slave capacitor C1. More specifically, the end P3 of each master capacitor CS is connected in series to the high-end 310 through the corresponding first master switch SW1 and the other end Q3 of each master capacitor CS is connected in series to the first slave capacitor C1 through the corresponding second master switch SW2.

One end of each switch element 341-34n is respectively and electrically connected to the voltage elements 331-33n, and the other end of each switch element 341-34n is electrically connected to a part of the slave capacitors. Each switch element 341-34n has a plurality of slave switch sets. The number of slave switch sets of each switch element 341-34n is equal to the number of the corresponding slave capacitors, to adjust the voltage of the master capacitor CS and the voltages of the slave capacitors C1-Cn according to turning on or turning off the slave switch sets of each switch element 341-34n. One end of each slave switch set of each switch element 341-34n is electrically connected to the corresponding voltage element. The other end of each slave switch set of each switch element 341-34n is respectively and electrically connected to the corresponding slave capacitor. For clarity, the following description further elaborates two slave switch sets SET1 and SET2 taken as an example of the slave switch sets of each switch element 341-34n.

For example, as shown in FIG. 4, the end of the switch element 341 is electrically connected to the voltage element 331 and the other end of the switch element 341 is respectively and electrically to the slave capacitor C1 and C2 (i.e., the part of the slave capacitors). The switch element 341 has two slave switch sets SET1 and SET2 (i.e., the plurality of the slave switch sets). The number of the slave switch sets SET1-SET2 of the switch element 341 is equal to the number of the corresponding slave capacitors C1-C2 to adjust the voltage of the master capacitor CS and the voltages of the slave capacitors C1 and C2 according to turning on or turning off the slave switch sets SET1-SET2 of the switch element 341. The ends of the slave switch sets SET1-SET2 of the switch element 341 are electrically connected to the corresponding voltage element 331. The other ends of the slave switch sets SET1-SET2 of the switch element 341 are respectively and electrically connected to the slave capacitors C1-C2 (i.e., the corresponding slave capacitors).

It is worth to note that the switch element 341-34n is only electrically connected to the part of the slave capacitors (e.g., the switch element 341 is electrically connected to the slave capacitors C1 and C2, and the switch element 34n is electrically connected to the slave capacitors Cn−1 and Cn), but all of the slave capacitors C1-Cn are electrically connected to at least one switch element 341-34n. Therefore, the voltage of the master capacitor CS and the voltages of the slave capacitors C1-Cn can be adjusted by turning on or turning off the slave switch sets of the switch elements 341-34n.

In the instant disclosure, each slave switch set has a first slave switch SA and a second slave switch SB. One end of the first slave switch SA is electrically connected to the end P3 of the master capacitor CS. The other end of the first slave switch SA is electrically connected to one end of the corresponding slave capacitor. One end of the second slave switch SB is electrically connected to the other end Q3 of the master capacitor CS. The other end of the second slave switch SB is electrically connected to the other end of the corresponding slave capacitor.

Taking the slave switch set SET1 and the slave capacitor C1 of the switch element 341 as an example, one end of the first slave switch SA is electrically connected to the end P3 of the master capacitor CS of the voltage element 331. The other end of the first slave switch SA is electrically connected to the end a of the slave capacitor C1. One end of the second slave switch SB is electrically connected to the other end Q3 of the master capacitor CS of the voltage element 331. The other end of the second slave switch SB is electrically connected to the other end b of the slave capacitor C1.

The controller 350 is electrically connected to the voltage elements 331-33n and the switch elements 341-34n. The controller 350 generates a plurality of driving signals St1-Stn. Each of the driving signals St1-Stn has a driving period (not shown in FIGs) to periodically control the first master switch SW1 and the second master switch SW2 of each voltage element 331-33n and the slave switch sets SET1-SET2 of each switch element 341-34n according to the driving signals St1-Stn (i.e., periodically turning on or turning off the first master switch SW1 and the second master switch SW2 of each voltage element 331-33n and the slave switch sets SET1-SET2 of each switch element 341-34n). The controller 350 can be a clock generator, waveform generator, or other electronic devices, which can periodically generate the driving signals St1-Stn. The instant disclosure is not limited thereto.

During the driving periods, the controller 350 simultaneously turns on the first master switch SW1 and the second switch SW2 of the voltage elements 331-33n at least once, and respectively turns on the slave switch sets SET1-SET2 of the switch elements 341-34n at least once. This means that the aforementioned switches are turned on at least once during the whole driving periods.

When the controller element 350 simultaneously turns on the first master switch SW1 and the second master switch SW2 of each voltage element 331-33n according to the driving signals St1-Stn, the controller element 350 turns off the slave switch sets of each switch element 341-34n. Then the multi-voltage driving circuit 300 increases the voltage of the master capacitor CS and the voltages of the slave capacitors C1-Cn according to the high voltage VH.

When the controller 350 respectively turns on the slave switche sets of each switch element 341-34n according to the driving signals St1-Stn, the controller 350 turns off the first master switch SW1 and the second master switch SW2 of the voltage elements 331-33n and the slave switch sets without the turned-on slave switch sets of the switch elements 341-34n. Then the multi-voltage driving circuit 300 averages the voltage of the master capacitor CS and the voltage of the slave capacitor corresponding to the turned-on slave switch set.

For example, when the controller 350 respectively turns on the slave switch set SET1 of the voltage elements 341-34n according to the driving signal St1-Stn, the controller 350 turns off the first master switch SW1 and the second master switch SW2 of the voltage elements 331-33n and the slave switch set SET2 of the switch elements 341-34n. Then the multi-voltage driving circuit 300 respectively averages the voltage of the master capacitor CS of the voltage elements 331-33n and the voltage of the slave capacitor corresponding to the slave switch set SET1 of the switch elements 341-34n. For example, the multi-voltage driving circuit 300 averages the voltages of the master capacitor CS of the voltage element 331 and the slave capacitor C1. The multi-voltage driving circuit 300 averages the voltages of the master capacitor CS of the voltage element 33n and the slave capacitor Cn−1.

It is worth to note that the multi-voltage driving circuit 300 simultaneously averages the voltage of the master capacitor CS of the voltage elements 331-33n and the voltage of the corresponding slave capacitors through the switch elements 341-34n. Therefore, the multi-voltage driving circuit 300 can simultaneously average many of the slave capacitors.

The driving periods can also be designed by the connecting sequence of the first master switch SW1 and the second master switch SW2 of each voltage element 331-33n, and the slave switch sets SET1-SET2 of each switch element 341-34n. Therefore, the controller 350 respectively turns on the first master switch SW1 and the second master switch SW2 of each voltage element 331-33n, and then respectively and sequentially turns on the slave switch sets SET1-SET2 of each switch element 341-34n. The driving period can be designed by another connecting sequence of the first master switch SW1 and the second master switch SW2 of each voltage element 331-33n, and the slave switch sets SET1-SET2 of each switch element 341-34n. For example, the controller 350 firstly turns on the first master switch SW1 and the second master switch SW2 of each voltage element 331-33n, then turns on the slave switch set SET2 of each switch element 341-34n, and finally turns on the slave switch set SET1 of each switch element 341-34n. The instant disclosure does not limit the sequence of turning on the aforementioned switches.

In the situation of the controller 350 continuously generating the driving periods, the multi-voltage driving circuit 300 continuously and rapidly averages the voltage of the master capacitor CS and the voltages of the slave capacitors C1-Cn, so that the voltages of the slave capacitors C1-Cn become equal gradually. The multi-voltage driving circuit 300 further generates a plurality of divided voltages V1-Vn. Each divided voltage V1-Vn is Vm=VL+m*(VH−VL)/(n+1), wherein 1<=m<=n.

As described in the aforementioned exemplary embodiments, the multi-voltage driving circuit 300 simultaneously averages the voltages of the master capacitor CS of the voltage elements 331-33n and the voltages of the slave capacitors C1-Cn through the switch elements 341-34n. Therefore, compared to the multi-voltage driving circuit 100 in FIG. 2 and the multi-voltage driving circuit 200 in FIG. 3, the multi-voltage driving circuit 300 can rapidly average the voltages of the slave capacitors C1-Cn to generate the accurate divided voltages V1-Vn.

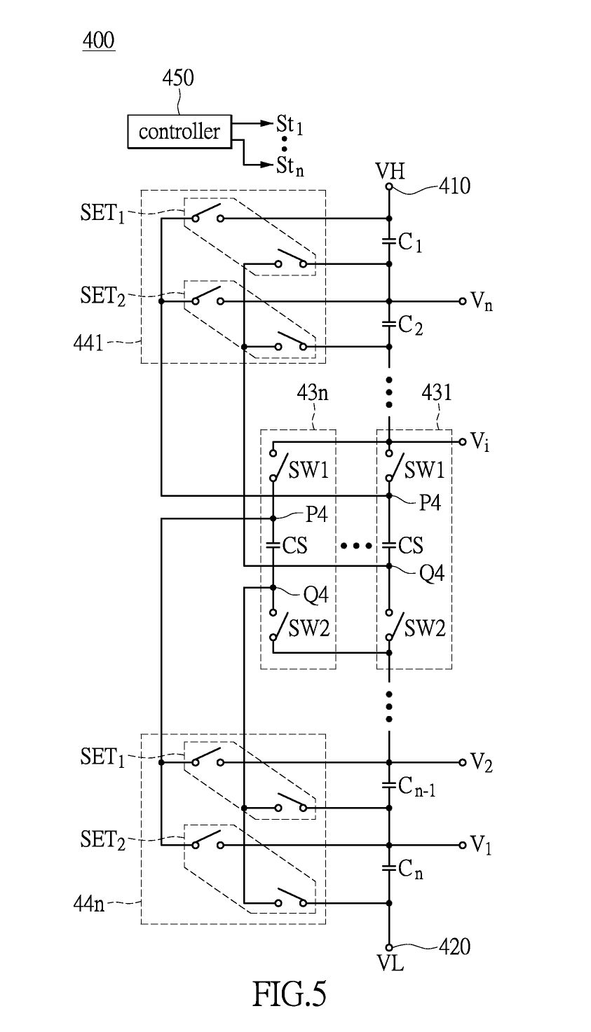

Next, please refer to FIG. 5, which shows a diagram of a multi-voltage driving circuit according to another exemplary embodiment of the instant disclosure. As shown in FIG. 5, the multi-voltage driving circuit 400 includes a high-end 410, a low-end 420, a plurality of slave capacitors C1-Cn, a plurality of voltage elements 431-43n, a switch element 440, and a controller 450. Compared to the multi-voltage driving circuit 300 in FIG. 4, the difference of the multi-voltage driving circuit 400 in FIG. 5 is that the voltage elements 431-43n are configured between two adjacent slave capacitors. More specifically, the end P4 of the master capacitor CS of each voltage element 431-43n is connected in series to one of two adjacent slave capacitors through the corresponding first master switch SW1. The end Q4 of the master capacitor CS of each voltage element 431-43n is connected in series to the other of two adjacent slave capacitors through the corresponding second master switch SW2.

Taking the voltage elements 431-43n connected in series between the fifth slave capacitor C5 and the sixth slave capacitor C6 (i.e., between two adjacent slaves) as an example, the end P4 of the master capacitor CS of each voltage element 431-43n is connected in series to the fifth slave capacitor C5 through the corresponding first master switch SW1. The end Q4 of the master capacitor CS of each voltage element 431-43n is connected in series to the sixth slave capacitor C6 through the corresponding second master switch SW2. The connection relationships and operations among the high-end 410, the low-end 420, the slave capacitors C1-Cn, the slave switch sets SET1-SET2, the voltage elements 431-43n, the switch elements 441-44n, and the controller 450 are the same as that of the high-end 310, the low-end 320, the slave capacitors C1-Cn, the slave switch sets SET1-SET2, the voltage elements 331-33n, the switch elements 341-34n, and the controller 350 as shown in FIG. 4, so their detailed description is omitted.

Therefore, in the situation of the controller 450 continuously generating the driving signals St1-Stn with the driving period, the multi-voltage driving circuit 400 continuously and rapidly averages the voltage of the master capacitor CS and the voltages of the slave capacitors C1-Cn, so that the voltages of the slave capacitors C1-Cn become equal gradually. The multi-voltage driving circuit 400 further generates a plurality of divided voltages V1-Vn. Each divided voltage V1-Vn is Vm=VL+m*(VH−VL)/(n+1), wherein 1<=m<=n.

As in the aforementioned exemplary embodiments, the multi-voltage driving circuits 300 and 400 are designed using the structures of the master capacitors CS, the slave capacitors C1-Cn, the first master switches SW1, the second master switches SW2, and the slave switch sets SET1-SETn. The master capacitors CS and the slave capacitors C1-Cn have no power consumption and the multi-voltage driving circuit 300 and 400 simultaneously averages the slave capacitors. Therefore, the multi-voltage driving circuits 300 and 400 generate the more accurate divided voltages V1-Vn. In addition, because the first master switches SW1, the second master switches SW2, and the slave switch sets SET1-SETn have less power consumption, the multi-voltage driving circuits 300 and 400 are adapted for low-power operation.

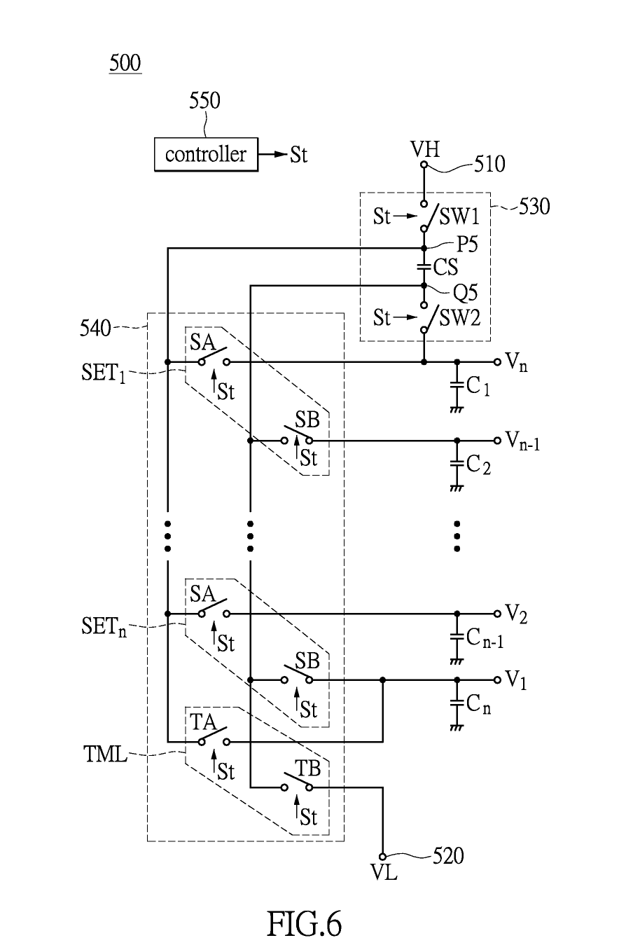

Next, please refer to FIG. 6, which shows a diagram of a multi-voltage driving circuit according to the other exemplary embodiment of the instant disclosure. As shown in FIG. 6, the multi-voltage driving circuits 500 includes a high-end 510, a low-end 520, a plurality of slave capacitors C1-Cn, a voltage element 530, a switch element 540, and a controller 550. The high-end 510 has a high voltage VH and the low-end 520 has a low voltage VL. The voltage element 530 is connected in series between the high-end 510 and the first slave capacitor C1. In the actual structure, the low-end 520 may connect to ground to cause the low voltage VL to be 0V, and the instant disclosure is not limited thereto.

The voltage element 530 has a master capacitor CS, a first master switch SW1, and a second master switch SW2. The first master switch SW1 is connected in series to one end P5 of the master capacitor CS. The second master switch SW2 is connected in series to the other end Q5 of the master capacitor CS. In the instant disclosure, the voltage element 530 is configured between the high-end VH and the first slave capacitor C1. More specifically, the end P5 of the master capacitor CS is connected in series to the high-end VH through the first master switch SW1. The other end Q5 of the master capacitor CS is connected in series to the first slave capacitor C1 through the second master switch SW2.

The switch element 540 is electrically connected among the voltage element 530, the slave capacitors C1-Cn, and the low-end 520. The switch element 540 has a plurality of slave switch sets SET1-SETn and an end switch set TML to adjust the voltage of the master capacitor CS and the voltages of the slave capacitors C1-Cn according to turning on or turning off the slave switch sets SET1-SETn and the end switch set TML. One end of each slave switch set SET1-SETn is electrically connected to the voltage element 530. The other end of each slave switch set SET1-SETn is sequentially and electrically connected to two slave capacitors.

Taking the slave switch sets SET1-SET2 and SETn as an example, one end of each slave switch set SET1-SET2 and SETn is electrically connected to the voltage element 530. The other end of the slave switch set SET1 is electrically connected to the slave capacitors C1-C2. The other end of the slave switch set SET2 is electrically connected to the slave capacitors C3-C4. The other end of the slave switch set SETn is electrically connected to the slave capacitors Cn−1-Cn. One end of the end switch set TML is electrically connected to the voltage element 530. The other end of the end switch set TML is electrically connected to the last slave capacitor Cn and the low-end 520. It is worth to note that one end of each slave capacitor C1-Cn is electrically connected to the corresponding slave switch set and the other end of each slave capacitor C1-Cn is electrically connected to ground.

In the instant disclosure, each slave switch set SET1-SETn has a first slave switch SA and a second slave switch SB. One end of the first slave switch SA is electrically connected to the end P5 of the master capacitor CS. The other end of the first slave switch SA is electrically connected to the first of two corresponding slave capacitors. One end of the second slave switch SB is electrically connected to the other end Q5 of the master capacitor CS. The other end of the second slave switch SB is electrically connected to the second of two corresponding slave capacitors.

Taking the slave switch set SET1 and the slave capacitors C1-C2 as an example, one end of the first slave switch SA is electrically connected to the end P5 of the master capacitor CS. The other end of the first slave switch SA is electrically connected to the slave capacitor C1. One end of the second slave switch SB is electrically connected to the other end Q5 of the master capacitor CS. The other end of the second slave switch SB is electrically connected to the slave capacitor C2. Besides, in the instant disclosure, the end switch set TML includes a first end switch TA and second end switch TB. One end of the first end switch TA is electrically connected to the end P5 of the master capacitor CS. The other end of the first end switch TA is electrically connected to the last slave capacitor Cn. One end of the second end switch TB is electrically connected to the other end Q5 of the master capacitor CS. The other end of the second end switch TB is electrically connected to the low-end 520.

The controller element 550 is electrically connected to the voltage element 530 and the switch element 540. The controller 550 generates a driving signal St with a driving period (not shown in FIGs), to control the first master switch SW1, the second master switch SW2, the slave switch sets SET1-SETn, and the end switch set TEL according to the driving signal St, i.e., periodically turning on or turning off the first master switch SW1, the second master switch SW2, the slave switch sets SET1-SETn, and the end switch set TEL. The controller 550 can be a clock generator, waveform generator, or other electronic devices, which can periodically generate the driving signal St. The instant disclosure is not limited thereto.

During the driving period, the controller 550 turns on the first master switch SW1 and the second master switch SW2 at least once, and respectively turns on the slave switch sets SET1-SETn and the end switch set TEL at least once. This means that the aforementioned switches are turned on at least once during the whole driving period. When the controller 550 turns on the first master switch SW1 and the second master switch SW2 according to the driving signal St, the controller 550 turns off the slave switch sets SET1-SETn and the end switch set TEL. Then the multi-voltage driving circuit 500 increases the voltage of the master capacitor CS and the voltages of the slave capacitors C1-Cn according to the high voltage VH.

When the controller 550 turns on the corresponding slave switch set according to the driving signal St, the controller 550 turns off the first master switch SW1, the second master switch SW2, the slave switch sets without the turned-on salve switch set, and the end switch set TEL. Then the multi-voltage driving circuit 500 averages the voltage of the master capacitor CS and the voltage of the slave capacitor corresponding to the turned-on slave switch set. For example, when the controller 550 turns on the slave switch set SET1 according to the driving signal St, the controller 550 turns off the first master switch SW1, the second master switch SW2, and the slave switch sets SET2-SETn. Then the multi-voltage driving circuit 500 averages the voltage of the master capacitor CS and the voltages of the slave capacitors C1-C2.

When the controller 550 turns on the end switch set TEL according to the driving signal St, the controller 550 turns off the first master switch SW1, the second master switch SW2, and the slave switch sets SET1-SETn. Then the multi-voltage driving circuit 500 averages the voltage of the master capacitor CS and the voltages of the slave capacitor Cn.

It is worth to note that the driving period can be designed by the connecting sequence of the first master switch SW1, the second master switch SW2, the slave switch sets SET1-SETn, and the end switch set TEL. Therefore, the controller 550 firstly turns on the first master switch SW1 and the second master switch SW2, and then sequentially turns on the slave switch sets SET1-SETn and the end switch set TEL. The driving period can be designed by other connecting sequences of the first master switch SW1, the second master switch SW2, the slave switch sets SET1-SETn, and the end switch set TEL. For example, the controller 550 firstly turns on the first master switch SW1 and the second master switch SW2, then sequentially turns on the odd slave switch sets SET1, SET3, . . . , SETn−1, then turns on the end switch set TEL, and finally sequentially turns on the even slave switch sets SET2, SET4, . . . , SETn. The instant disclosure does not limit the sequence of turning on the aforementioned switches.

In the situation of the controller 550 continuously generating the driving period, the multi-voltage driving circuit 500 continuously averages the voltage of the master capacitor CS and the voltages of the slave capacitors C1-Cn, so that the voltages of the slave capacitors C1-Cn become equal gradually. The multi-voltage driving circuit 500 further generates a plurality of divided voltages V1-Vn. Each divided voltage V1-Vn is Vm=VL+m*(VH−VL)/(n+1), wherein 1<=m<=n.

As in the aforementioned exemplary embodiments, the multi-voltage driving circuits 500 is designed using the structures of the master capacitor CS, the slave capacitors C1-Cn, the first master switch SW1, the second master switch SW2, the slave switch sets SET1-SETn, and the end switch set TML. The master capacitors CS and the slave capacitors C1-Cn have no power consumption. Therefore, the multi-voltage driving circuit 500 generates the accurate divided voltages V1-Vn. In addition, because the first master switch SW1, the second master switch SW2, and the slave switch sets SET1-SETn have less power consumption, the multi-voltage driving circuit 500 is adapted for low-power operation.

In summary, the multi-voltage driving circuit averages the voltage of the master capacitor and the voltages of the slave capacitors by turning on or turning off the switches continuously, thereby the voltages of all capacitors become equal gradually and the multi-voltage driving circuit further generates a plurality of divided voltages. Because all capacitors have no power consumption and the switches have less power consumption, the multi-voltage driving circuit is adapted for low-power operation.

The above-mentioned descriptions represent merely the exemplary embodiment of the present disclosure, without any intention to limit the scope of the present disclosure thereto. Various equivalent changes, alterations or modifications based on the claims of present disclosure are all consequently viewed as being embraced by the scope of the present disclosure.

What is claimed is:

1. A multi-voltage driving circuit, comprising:
a high-end, having a high voltage;
a low-end, having a low voltage;
a plurality of slave capacitors, connected in series between the high-end and the low-end;
a voltage element, connected in series to the high-end, the slave capacitors, and the low-end, and having a master capacitor, a first master switch, and a second master switch, wherein the first master switch is connected in series to one end of the master capacitor, and the second master switch is connected in series to the other end of the master capacitor;
a switch element, electrically connected among the voltage element and the slave capacitors, and having a plurality of slave switch sets, wherein one end of each slave switch set is electrically connected to the voltage element, and the other end of each slave switch is respectively and electrically connected to the slave capacitors; and
a controller, electrically connected to the voltage element and the switch element, and configured for generating a driving signal with a driving period to periodically control the first master switch, the second master switch, and the slave switch sets according to the driving signal;
wherein, the controller simultaneously turns on the first master switch and the second master switch at least once during the driving period, and when the controller simultaneously turns on the first master switch and the second master switch, turns off the slave switch sets;
wherein, the controller respectively turns on the slave switch sets at least once during the driving period, and when the controller turns on the corresponding slave switch set, turns off the first master switch, the second master switch, and the slave switch sets without the turned-on slave switch sets.

2. The multi-voltage driving circuit according to claim 1, wherein each slave switch set comprises a first slave switch and a second slave switch, one end of the first slave switch is electrically connected to the end of the master capacitor, the other end of the first slave switch is electrically connected to one end of the corresponding slave capacitor, one end of the second slave switch is electrically connected to the other end of the master capacitor, and the other end of the second slave switch is electrically connected to the other end of the corresponding slave capacitor.

3. The multi-voltage driving circuit according to claim 1, wherein the voltage element is configured between the high-end and the first slave capacitor, the end of the master capacitor is connected in series to the high-end through the first master switch, and the other end of the master capacitor is connected in series to the first slave capacitor through the second master switch.

4. The multi-voltage driving circuit according to claim 1, wherein the voltage element is configured between two adjacent slave capacitors, the end of the master capacitor is connected in series to one of two adjacent slave capacitors through the first master switch, and the other end of the master capacitor is connected in series to the other of two adjacent slave capacitors through the second master switch.

5. The multi-voltage driving circuit according to claim 1, wherein the voltage element is configured between the low-end and the last slave capacitor, the end of the master capacitor is connected in series to the last slave capacitor through the first master switch, and the other end of the master capacitor is connected in series to the low-end through the second master switch.

6. A multi-voltage driving circuit, comprising:
a high-end, having a high voltage;
a low-end, having a low voltage;
a plurality of slave capacitors, connected in series between the high-end and the low-end;
a plurality of voltage elements, connected in series to the high-end, the slave capacitors, and the low-end, and the voltage elements connected in parallel with each other, wherein each voltage element has a master capacitor, a first master switch, and a second master switch, the first master switch is connected in series to one end of the master capacitor, and the second master switch is connected in series to the other end of the master capacitor;
a plurality of switch elements, one end of each switch element is respectively and electrically connected to the voltage elements, and the other end of each switch element is respectively and electrically connected to a part of the slave capacitors, wherein each switch element has a plurality of slave switch sets, the number of the slave switch sets of each switch element is equal to the number of the corresponding slave capacitors, one end of each slave switch set is electrically connected to the corresponding voltage element, the other end of each slave switch set is electrically connected to the corresponding slave capacitor, and the slave capacitors are respectively and electrically connected to at least one switch element; and
a controller, electrically connected to the voltage elements and the switch elements, and configured for generating a plurality of driving signals, each driving signal having a driving period, and the controller periodically controlling the first master switch and the second master switch of the voltage elements and the slave switch sets of the switch elements according to the driving signals;
wherein, the controller simultaneously turns on the first master switch and the second master switch of the voltage elements at least once during the driving periods, and when the controller simultaneously turns on the first master switch and the second master switch of the voltage elements, turns off the slave switch sets of the switch elements;
wherein, the controller respectively turns on the slave switch sets of the switch elements at least once during the driving periods, and when the controller respectively turns on the slave switch sets of the switch elements, turns off the first master switch and the second master switch of the voltage elements and the slave switch sets without the turned-on slave switch sets of the switch elements.

7. The multi-voltage driving circuit according to claim 6, wherein each slave switch set comprises a first slave switch and a second slave switch, one end of the first slave switch is electrically connected to the end of the corresponding master capacitor, the other end of the first slave switch is electrically connected to one end of the corresponding slave capacitor, one end of the second slave switch is electrically connected to the other end of the corresponding master capacitor, and the other end of the second slave switch is electrically connected to the other end of the corresponding slave capacitor.

8. The multi-voltage driving circuit according to claim 6, wherein the voltage elements are configured between the high-end and the first slave capacitor, the end of each master capacitor is connected in series to the high-end through the corresponding first master switch, and the other end of each master capacitor is connected in series to the first slave capacitor through the corresponding second master switch.

9. The multi-voltage driving circuit according to claim 6, wherein the voltage elements are configured between two adjacent slave capacitors, the end of each master capacitor is connected in series to one of two adjacent slave capacitors through the corresponding first master switch, and the other end of each master capacitor is connected in series to the other of two adjacent slave capacitors through the corresponding second master switch.

10. The multi-voltage driving circuit according to claim 6, wherein the voltage elements are configured between the last slave capacitor and the low-end, the end of each master capacitor is connected in series to the last slave capacitor through the corresponding first master switch, and the other end of each master capacitor is connected in series to the low-end.

11. A multi-voltage driving circuit, comprising:
a high-end, having a high voltage;
a low-end, having a low voltage;
a plurality of slave capacitors;
a voltage element, connected in series between the high-end and the first slave capacitor, and having a master capacitor, a first master switch, and a second master switch, wherein the first master switch is connected in series to one end of the master capacitor, and the second master switch is connected in series to the other end of the master capacitor;
a switch element, electrically connected among the voltage element, the slave capacitors, and the low-end, and having a plurality of slave switch sets and an end switch set, wherein one end of each slave switch set is electrically connected to the voltage element, the other end of each slave switch set is sequentially and electrically connected to two slave capacitors, one end of the end switch set is electrically connected to the voltage element, the other end of the end switch set is electrically connected to the last slave capacitor and the low-end, one end of each slave capacitor is electrically connected to the corresponding slave switch set, and the other end of each slave capacitor is connected to ground; and
a controller, electrically connected to the voltage element and the switch element, and configured for generating a driving signal with a driving period to control the first master switch, the second master switch, the slave switch sets, and the end switch set;
wherein, the controller simultaneously turns on the first master switch and the second master switch at least once during the driving period, and when the controller simultaneously turns on the first master switch and the second master switch, turns off the slave switch sets and the end switch set;
wherein, the controller respectively turns on the slave switch sets and the end switch set at least once during the driving period, when the controller turns on the corresponding slave switch set, turns off the first master switch, the second master switch, the end switch set, and the slave switch sets without the turned-on switch set, and when the controller turns on the corresponding end switch set, turns off the first master switch, the second master switch, and the slave switch sets.

12. The multi-voltage driving circuit according to claim 11, wherein each slave switch set comprises a first slave switch and a second slave switch, one end of the first slave switch is electrically connected to the end of the master capacitor, the other end of the first slave switch is electrically connected to the first of the two corresponding slave capacitors, one end of the second slave switch is electrically connected to the other end of the master capacitor, and the other end of the second slave switch is electrically connected to the second of the two corresponding slave capacitors.

13. The multi-voltage driving circuit according to claim 12, wherein the end switch set comprises a first end switch and a second end switch, one end of the first end switch is electrically connected to the end of the master capacitor, the other end of the first end switch is electrically connected to the last slave capacitor, one end of the second end switch is electrically connected to the other end of the master capacitor, and the other end of the second end switch is electrically connected to the low-end.
